(19) United States
(12) Patent Application Publication
(10) Pub. No.: US 2026/0353683 A1
(43) Pub. Date: Nov. 5, 2026

(54) SEMICONDUCTOR DEVICE AND METHOD OF MANUFACTURING THE SAME

(71) Applicant: Taiwan Semiconductor Manufacturing Company, LTD., Hsinchu (TW)

(72) Inventor: Hung-Te Lin, Hsinchu (TW)

(21) Appl. No.: 19/198,012

(22) Filed: May 3, 2025

(51) Int. Cl. H10D 1/68; H10D 1/00

(52) U.S. Cl. CPC H10D 1/716; H10D 1/042; H10D 1/714

(57) ABSTRACT

Capacitors in a semiconductor device include a dielectric buffer structure on one or more exposed sides at least one conductive layer. The capacitor may have multiple alternating conductive/metal layers and insulating/dielectric layers, such as an MIMIM or MIMIMIM capacitor. The dielectric buffer structure can be formed by plasma treatment of the exposed side(s) of the conductive layer(s). Electrical contacts to adjacent conductive layers may be separated from each other, for example on different sides of the capacitor. This reduces current leakage and improves the capacitance of the capacitor.

### BACKGROUND

Integrated circuits are formed on a semiconductor wafer. Photolithographic patterning processes use ultraviolet light to transfer a desired mask pattern to a photoresist on a semiconductor wafer. Etching processes may then be used to transfer to the pattern to a layer below the photoresist. This process is repeated multiple times with different patterns to build different layers on the wafer substrate and make a useful device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a Y-axis cross-sectional view of a capacitor, in accordance with some embodiments. Here, the capacitor has a stepped edge structure.

FIG. 1B is a plan view of another capacitor with a stepped edge structure.

FIG. 1C is a magnified view of one stepped edge of the capacitor of FIG. 1A, showing more detail. Here, a dielectric buffer structure is formed on only the sides of each conductive layer.

FIG. 1D is a magnified view of another embodiment of the stepped edge of the capacitor of FIG. 1A, showing more detail. Here, the dielectric buffer structure is formed on the sides and a portion of the upper surface on some of the conductive layers.

FIG. 2 is a circuit diagram of the capacitor of FIG. 1A.

FIG. 3A is a Y-axis cross-sectional view of a capacitor, in accordance with some embodiments. Here, the capacitor has an aligned edge structure.

FIG. 3B is a plan view of the capacitor of FIG. 3A.

FIG. 3C is a magnified view of one edge of the capacitor of FIG. 3A, showing more detail. Here, a dielectric buffer structure is formed on only the sides of each conductive layer.

FIG. 4 is a first method for making a capacitor, in accordance with some embodiments. In this method, a stepped edge capacitor is made.

FIG. 5 is a Y-axis cross-sectional view of a substrate and trenches in the substrate.

FIG. 6 is a Y-axis cross-sectional view of the substrate after an isolation layer has been formed, and conductive layers and insulator layers have been deposited over the substrate, and a capping layer has been deposited over the substrate.

FIG. 7 is a magnified Y-axis cross-sectional view of the isolation layer and the capacitor layers.

FIG. 8 is a Y-axis cross-sectional view of the capacitor after patterning and etching of the capping layer, the fourth conductive layer, and the third insulator layer.

FIG. 9 is a Y-axis cross-sectional view of the capacitor after a first plasma treatment using an oxygen-containing gas to form a dielectric buffer structure in the fourth conductive layer.

FIG. 10 is a Y-axis cross-sectional view of the capacitor after patterning and etching of the third conductive layer and the second insulator layer.

FIG. 11 is a Y-axis cross-sectional view of the capacitor after a second plasma treatment using an oxygen-containing gas to form a dielectric buffer structure in the third conductive layer.

FIG. 12 is a Y-axis cross-sectional view of the capacitor after patterning and etching of the second conductive layer and the first insulator layer.

FIG. 13 is a Y-axis cross-sectional view of the capacitor after a third plasma treatment using an oxygen-containing gas to form a dielectric buffer structure in the second conductive layer.

FIG. 14 is a Y-axis cross-sectional view of the capacitor after patterning and etching of the first conductive layer.

FIG. 15A is a Y-axis cross-sectional view of a first embodiment of the capacitor after a fourth plasma treatment using an oxygen-containing gas to form a dielectric buffer structure in the first conductive layer.

FIG. 15B is a Y-axis cross-sectional view of a second embodiment of the capacitor. Here, only one plasma treatment using an oxygen-containing gas is used to concurrently form dielectric buffer structures in the four conductive layers.

FIG. 15C is a Y-axis cross-sectional view of a third embodiment of the capacitor. Here, the insulator layers were completely removed during etching to expose the non-overlapping upper surface of the stepped edge of each conductive layer. As a result, the dielectric buffer structure is present along the sides and on the non-overlapping upper surface of the three lower conductive layers.

FIG. 16 is a Y-axis cross-sectional view of the capacitor after a contact stop layer has been deposited over the substrate.

FIG. 17 is a second method for making a capacitor, in accordance with some embodiments. In this method, an aligned edge capacitor is made.

FIG. 18 is a Y-axis cross-sectional view after a first mask is patterned.

FIG. 19 is a Y-axis cross-sectional view after etching to form trenches through the capping layer and the fourth conductive layer down to the third insulator layer.

FIG. 20 is a Y-axis cross-sectional view after a second mask is patterned.

FIG. 21 is a Y-axis cross-sectional view after etching to extend some trenches through the third insulator layer and the third conductive layer down to the second insulator layer.

FIG. 22 is a Y-axis cross-sectional view after a third mask is patterned.

FIG. 23 is a Y-axis cross-sectional view after etching to extend some trenches through the second insulator layer and the second conductive layer down to the first insulator layer.

FIG. 24 is a Y-axis cross-sectional view after a fourth mask is patterned.

FIG. 25 is a Y-axis cross-sectional view after etching to extend some trenches through the first insulator layer and the first conductive layer down to the isolation layer.

FIG. 26 is a Y-axis cross-sectional view of the capacitor after plasma treatment using an oxygen-containing gas is used to concurrently form dielectric buffer structures in the four conductive layers.

FIG. 27 is a Y-axis cross-sectional view of the capacitor after a contact stop layer has been deposited over the substrate.

FIG. 28 is a Y-axis cross-sectional view of the capacitor after interlayer dielectric (ILD) layer has been deposited over the substrate.

FIG. 29 is a Y-axis cross-sectional view of the capacitor after patterning and etching to form via openings in the trenches that extend to each conductive layer.

FIG. 30 is a Y-axis cross-sectional view of the capacitor after forming a barrier layer in the via openings, and then filling the via openings to form electrical contacts to each conductive layer.

FIG. 31 is a Y-axis cross-sectional view of the capacitor after forming contact pads that are electrically connected to the electrical contacts.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The terms “horizontal” and “vertical” as used herein are also spatially relative terms. The term “horizontal” refers to planes parallel to that of the surface of the wafer substrate, and the term “vertical” refers to planes that intersect the wafer substrate and form a substantially perpendicular angle with the wafer substrate. “Length” and “width” are measured in the horizontal plane, while “height” or “thickness” or “depth” are measured in the vertical direction. The “length” is arbitrarily designated in the X-axis, and the “width” is arbitrarily designated in the Y-axis. The term “length” should not be construed as always having a greater value than the “length”.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The present disclosure relates to systems and devices which are made up of multiple components and/or different layers. When the terms “on” or “upon” or “over” are used with reference to two different components or layers, they indicate merely that one component/layer is on or upon or over the other component layer. These terms do not require the two components/layers to directly contact each other, and permit other components/layers to be between them. The term “directly” may be used to indicate two components/layers directly contact each other without any other components/layers in between them. In addition, when referring to performing process steps to a component/substrate, this should be construed as performing such steps to whatever layers may be present on the component/substrate as well, which will depend on the context.

The present disclosure relates to capacitors that can be used in a semiconductor device, and to methods for making and using such capacitors. A capacitor is a passive electrical component used to store an electrical charge. Capacitors are widely used, for example in semiconductor devices to block direct current but permit alternating current to pass, or for storing data such as in DRAM or RRAM. A capacitor contains two relatively thick conductive layers separated by a relatively thin insulator layer. Current leakage can occur where the two conductive layers are relatively close to each other (particularly their edges) because the insulator layer is not perfectly insulating. In the present disclosure, a dielectric buffer structure is formed upon the exposed sides and surfaces of one or more of the conductive layers to reduce current leakage.

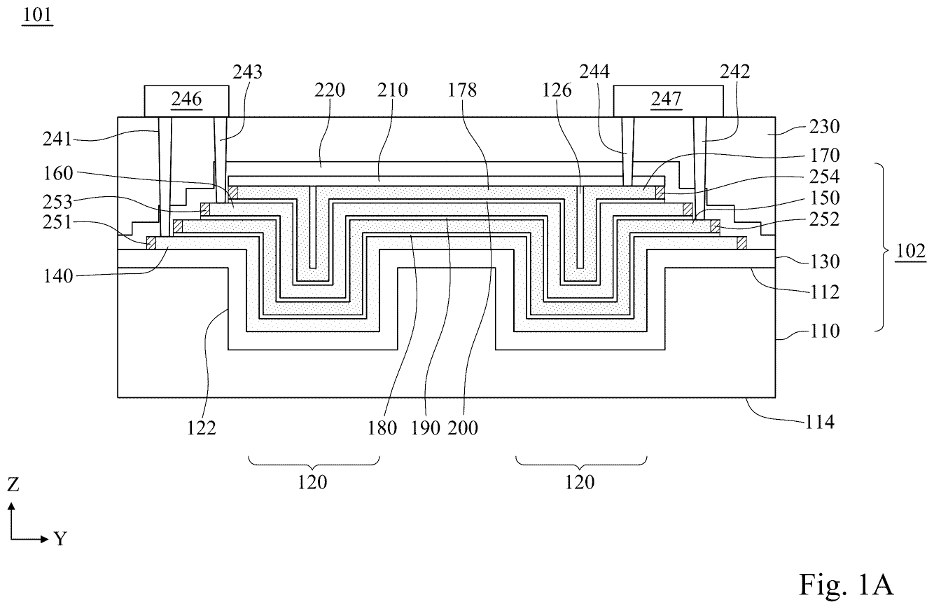

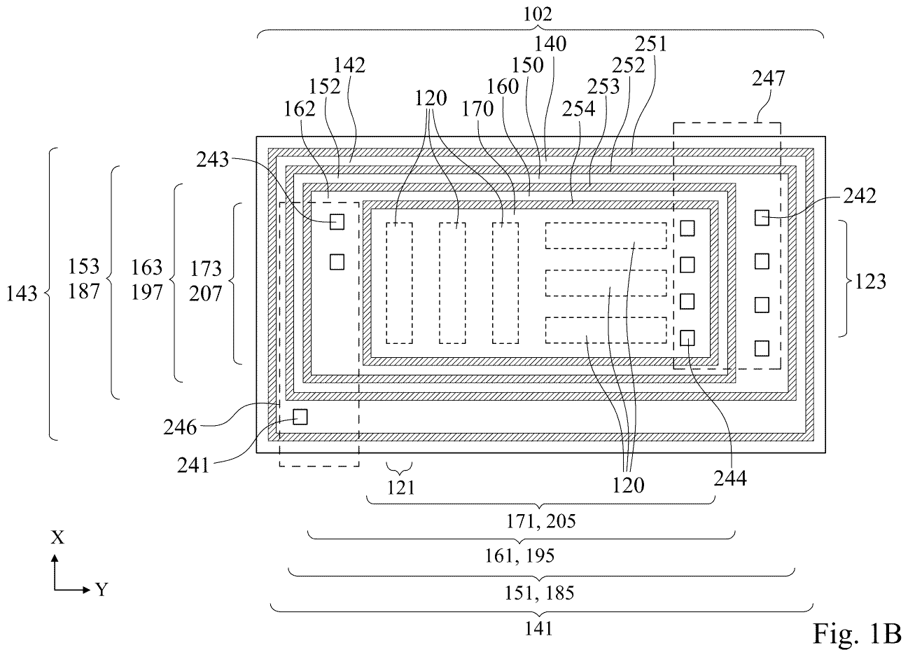

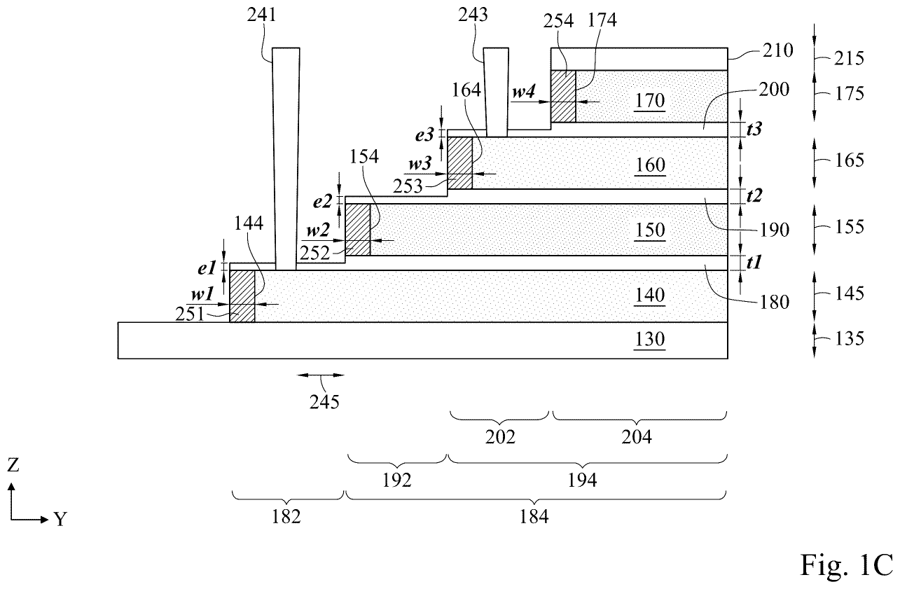

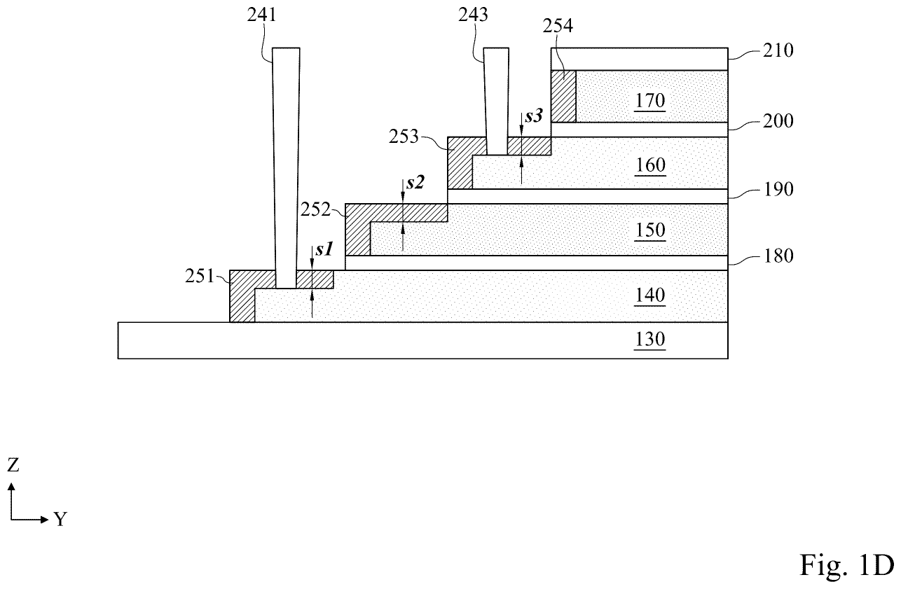

FIG. 1A is a cross-sectional view of one example of a semiconducting device 101 with a capacitor 102 of the present disclosure, in accordance with some embodiments. Here, the capacitor has a stepped edge structure. FIG. 1B is a plan view of a capacitor similar to that of FIG. 1A. A general description of the capacitor structure is first provided, followed by a more detailed description of the dielectric buffer structure.

Referring first to FIG. 1A, the semiconducting device includes a substrate 110 that has an upper surface 112 and a lower surface 114. Two vertical trenches 120 extend into the substrate from the upper surface 112, which can be deep trenches or shallow trenches. An isolation layer 130 covers the upper surface 112 of the substrate 110 and the surfaces of the trenches 120. The isolation layer is formed from an electrically insulating dielectric material.

In the plan view of FIG. 1B, six rectangular trenches 120 are shown. Three trenches are oriented in the X-axis, with their length being greater than their width. Three trenches are oriented in the Y-axis, with their width being greater than their length. This may be done, for example, to reduce or balance stresses. Generally, any number of trenches may be present, having any shape, and oriented in any horizontal direction as desired. In some embodiments, the trench width 121 and trench length 123 may independently vary from about 1,000 angstroms to about 10,000 angstroms. However, other values and ranges for each of these measurements are also within the scope of this disclosure.

Referring back to FIG. 1A, the capacitor 102 is formed from alternating layers of electrically conductive layers and electrical insulator layers to form an interleaved capacitor. In this example, the capacitor is formed from four conductive layers and three insulator layers. However, generally, the capacitor may be formed from any desired number of conductive layers and insulator layers.

Here, a first conductive layer 140 is formed upon the isolation layer 130. The first conductive layer conforms to the surfaces 122 of the trenches, and has a generally uniform thickness across the entire layer, whether running horizontally or vertically.

A first insulator layer 180 contacts the first conductive layer 140. The first insulator layer also conforms to the sidewalls and the surfaces of the trenches, and has a generally uniform thickness across the entire layer.

A second conductive layer 150, second insulator layer 190, third conductive layer 160, third insulator layer 200, and fourth conductive layer 170 are also shown, and may be described in similar terms as those used for the first conductive layer 140 and the first insulator layer 180. The fourth conductive layer may also be referred to as the upper conductive layer 178 of the capacitor in this embodiment.

The first insulator layer 180 is located between the first conductive layer 140 and the second conductive layer 150. The second insulator layer 190 is located between the second conductive layer 150 and the third conductive layer 160. The third insulator layer 200 is located between the third conductive layer 160 and the fourth conductive layer 170.

The illustrated capacitor has a stepped edge profile. As labeled in FIG. 1B, the first conductive layer 140 has a width 141 that is greater than the width 151 of the second conductive layer 150. Similarly, the width 141 of the first conductive layer is also greater than the width 161 of the third conductive layer 160 and the width 171 of the fourth conductive layer 170. The second conductive layer 150 has a width 151 that is greater than the width 161 of the third conductive layer 160, as well as the width 171 of the fourth conductive layer 170. The third conductive layer 160 has a width 161 that is greater than the width 171 of the fourth conductive layer 170. The width 171 of the fourth conductive layer is less than the widths 141, 151, 161 of the other three conductive layers.

As illustrated in FIG. 1B, the first conductive layer 140 has a length 143 that is greater than the length 153 of the second conductive layer 150. Similarly, the length 143 of the first conductive layer is also greater than the length 163 of the third conductive layer 160 and the length 173 of the fourth conductive layer 170. The second conductive layer 150 has a length 153 that is greater than the length 163 of the third conductive layer 160, as well as the length 173 of the fourth conductive layer 170. The third conductive layer 160 has a length 163 that is greater than the length 173 of the fourth conductive layer 170. The length 173 of the fourth conductive layer is less than the lengths 143, 153, 163 of the other three conductive layers.

More generally, in a stepped edge profile, each conductive layer 140, 150, 160 besides the upper conductive layer 178 has a non-overlapping upper surface area 142, 152, 162, relative to the other conductive layers only and not determined with respect to the insulator layers. Put another way, the conductive layer closer to the substrate has a larger plan surface area compared to a conductive layer further away from the substrate. In FIG. 1B, the non-overlapping upper surface area is shown on all four sides of each conductive layer, or in other words along the perimeter of each conductive layer. However, this is not required. For example, the non-overlapping upper surface area may be present on only one, two, or three sides of a given conductive layer, and the location of the non-overlapping upper surface area can vary between the conductive layers as desired.

The insulator layers, though not visible in FIG. 1B, can be described in the same way. The first insulator layer 180 has a width 185 that is greater than the width 195 of the second insulator layer 190, as well as the width 205 of the third insulator layer 200. The second insulator layer 190 has a width 195 that is greater than the width 205 of the third insulator layer 200. The width 205 of the third insulator layer is less than the widths 185, 195 of the other two insulator layers. The first insulator layer 180 has a length 187 that is greater than the length 197 of the second insulator layer 190, as well as the length 207 of the third insulator layer 200. The second insulator layer 190 has a length 197 that is greater than the length 207 of the third insulator layer 200. The length 207 of the third insulator layer is less than the lengths 187, 197 of the other two insulator layers. Generally, the dimensions of the first insulator layer correspond to the dimensions of the second conductive layer, etc. More broadly, generally the dimensions of the nth insulator layer correspond to the dimensions of the (n+1) conductive layer, where n is the lower layer of the capacitor (i.e. closer to the substrate).

Referring back to FIG. 1A, a capping layer 210 is present over the upper conductive layer of the capacitor. The capping layer is used as an etch stop layer, and may be made from any suitable dielectric material.

A cavity 126 may be present above each trench 120 between the upper conductive layer 178 and the capping layer 210. The cavity may be used to reduce stresses. The cavity generally contains air or another gas, and thus acts as an electrical insulator.

A contact stop layer 220 is present over the entire capacitor 102, including the capping layer 210 and the non-overlapping upper surfaces of each conductive layer. The contact stop layer also covers the upper surface 112 of the substrate. The contact stop layer can also be used as an etch stop layer, and may be made from any suitable dielectric material. In particular embodiments, the capping layer 210 and the contact stop layer 220 are made from different dielectric materials.

An interdielectric (ILD) layer 230 covers the substrate 110 and the capacitor 102. Referring now to both FIG. 1A and FIG. 1B, electrical contacts/vias 241, 242, 243, 244 are shown extending through the ILD layer 230 to contact each conductive layer 140, 150, 160, 170 along their perimeter. The electrical contacts extend from a conductive layer to a contact pad 246, 247. As illustrated, the first contact pad 246 is electrically connected to the first conductive layer 140 and the third conductive layer 160. The second contact pad 247 is electrically connected to the second conductive layer 150 and the fourth conductive layer 170. Generally, adjacent conductive layers should not be electrically connected to the same contact pad.

The contact pads 246, 247 may have any desired shape. For example, the two contact pads 246, 247 are shown in FIG. 1B in dotted line as having different dimensions.

Any number of vias may be made to each conductive layer. For example, as best seen in FIG. 1B, one via 241 contacts the first conductive layer 140, two vias 243 contact the third conductive layer 160, and four vias 242, 244 contact each of the second conductive layer 150 and the fourth conductive layer 170. Similarly, the electrical contacts to each conductive layer can be placed on any desired location upon the non-overlapping surface area. For example, the via 241 to the first conductive layer 140 is illustrated along the bottom, the vias 243 to the third conductive layer are illustrated along the left side, and the vias 242, 244 to the second conductive layer and the fourth conductive layer are illustrated along the right side.

FIG. 1C is a magnified view of one stepped edge of the capacitor of FIG. 1A, showing more detail and with some layers removed for clarity. In particular embodiments, the isolation layer 130 has a thickness 135 of about 50 angstroms to about 1,000 angstroms. In particular embodiments, the capping layer 210 has a thickness 215 of about 200 angstroms to about 600 angstroms. In particular embodiments, each conductive layer 140, 150, 160, 170 may independently have a thickness 145, 155, 165, 175 of about 150 angstroms to about 500 angstroms. In particular embodiments, each insulator layer 180, 190, 200 may independently have a thickness t1, t2, t3 of about 30 angstroms to about 150 angstroms. However, other ranges and values for each of these thicknesses are within the scope of the present disclosure.

The thickness of each insulator layer is indicated in the central portion 184, 194, 204 of the dielectric area, which is present in the overlapping area between conductive layers. As illustrated here, the thickness e1, e2, e3, of each insulator layer outer portion 182, 192, 202 in the non-overlapping upper surface area may be reduced (though still greater than zero). In particular embodiments, the thickness of the outer portion may be zero, or may be a non-zero value, such as from greater than zero to about 50 angstroms, or from about 10 nm to about 50 angstroms, although other ranges and values are also within the scope of the present disclosure. Generally, then, e1<t1, e2<t2, and e3<t3. Again, the non-overlapping surface area of a given conductive layer is only determined relative to the conductive layers above it.

In addition, one or more of the conductive layers includes a dielectric buffer structure. In FIG. 1C, a first dielectric buffer structure 251 is present on one or more exposed sides 144 of the first conductive layer 140. The first dielectric buffer structure 251 has a width w1. A second dielectric buffer structure 252 is present on the exposed side 154 of the second conductive layer 150. The second dielectric buffer structure 252 has a width w2. A third dielectric buffer structure 253 is present on the exposed side 164 of the third conductive layer 160. The third dielectric buffer structure 253 has a width w3. A fourth dielectric buffer structure 254 is present on the exposed side 174 of the fourth conductive layer 170. The fourth dielectric buffer structure 254 has a width w4. Each dielectric buffer structure has the same height or thickness as its conductive layer. Depending on the manufacturing process, w4≥w3≥w2≥w1. In particular embodiments, each dielectric buffer structure independently has a width of about 6 nanometers (nm) to about 50 nanometers, though other ranges and values are within the scope of the present disclosure. For comparison, the width of the capacitor may be in the micrometer range. It is noted that a minimum distance 245 of about 35 nanometers should be maintained between the dielectric buffer structure and the electrical contact.

Generally, the dielectric buffer structure is formed by oxidation of the conductive layer. For example, the conductive layer may be formed from a metal or metal alloy such as Ti, Ta, titanium nitride (TiN), or tantalum nitride (TaN), or doped polysilicon. When oxidized, these materials can form titanium oxide, tantalum oxide, titanium oxynitride (TiOxNy), and tantalum oxynitride (TaOxNy), which can be electrical insulators, for example when x=1.5 to 2.0 and y=0.1 to 0.2. The dielectric buffer structure is desirably not a metal oxide semiconductor, but is an electrical insulator.

In the embodiment of FIG. 1C, the dielectric buffer structure is formed on only the exposed side of a conductive layer. However, in another embodiment shown in FIG. 1D, the dielectric buffer structure is formed on the sides and the non-overlapping upper surface on the three conductive layers 140, 150, 160 which are not covered by the capping layer 210, or in other words all conductive layers except for the upper conductive layer 178. Put another way, the dielectric buffer structure is formed from a side portion and an upper portion. In particular embodiments, the thickness s1, s2, s3 of each upper portion may independently range from about 5 angstroms to about 950 angstroms, though other ranges and values are within the scope of the present disclosure. Depending on the manufacturing process, s3≥s2≥s1.

Referring back to FIG. 1B, in this example, each conductive layer has a four-sided rectangular shape in the plan view, and the dielectric buffer structure 251, 252, 253, 254 is illustrated on all four sides of each conductive layer. However, this is not required, and the dielectric buffer structure may be present on fewer than all sides of the conductive layer. For example, the dielectric buffer structure may be present on only one, two, or three sides. In particular embodiments, the dielectric buffer structure is present at least on the side(s) where electrical contacts to the conductive layer are formed. The conductive layers may also have a different shape as desired, such as circular, triangular, or hexagonal, octagonal, as non-limiting examples.

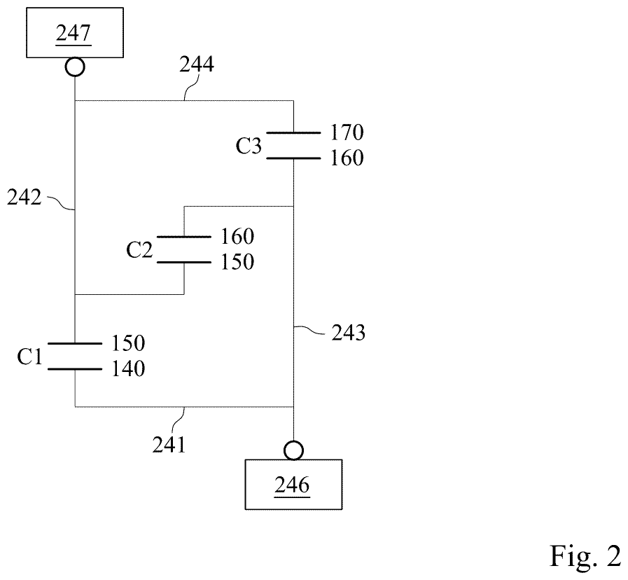

FIG. 2 is an electrical diagram describing the structure of the capacitor 102 of FIG. 1A. The overall capacitor may be described as having an overall capacitance corresponding to that of three capacitors in parallel, formed by the combinations of the four adjacent conductive layers 140, 150, 160, 170 as electrically connected to the contact pads 246, 247 through the electrical contacts 241, 242, 243, 244.

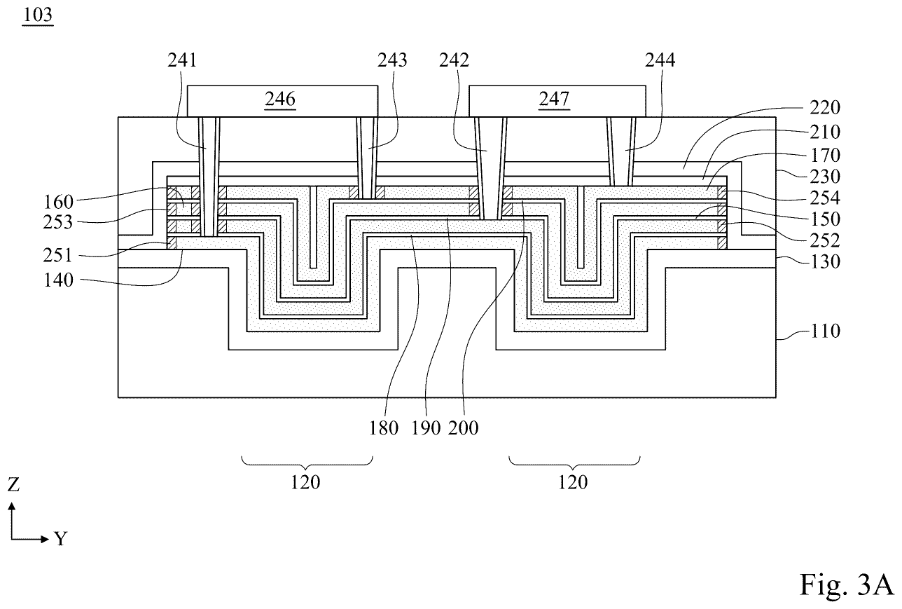

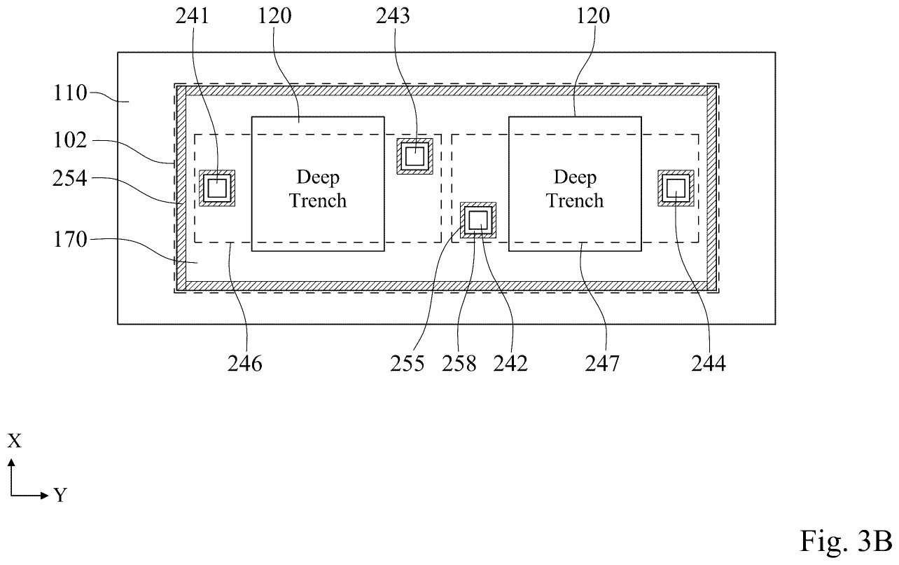

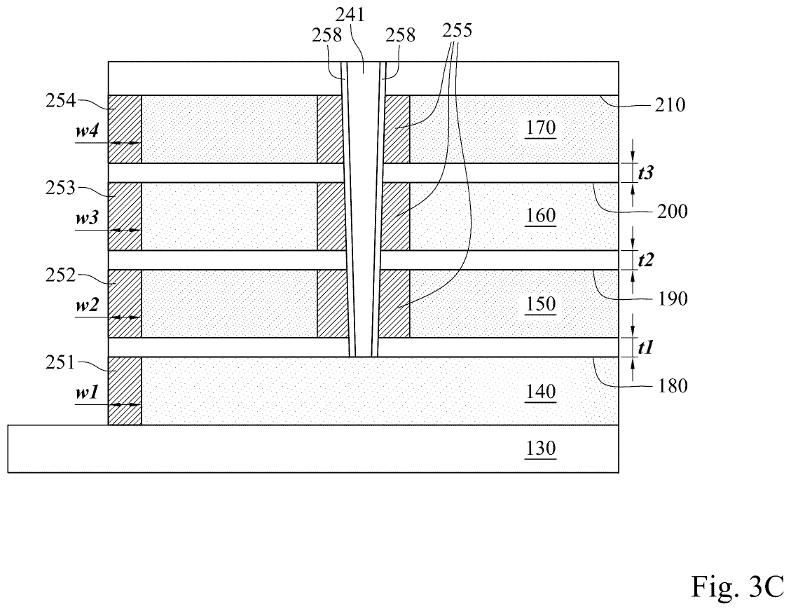

FIG. 3A is a cross-sectional view of another example of a semiconducting device 103 with a capacitor 102 of the present disclosure, in accordance with some embodiments. Here, the capacitor has an aligned edge structure. FIG. 3B is a plan view of the capacitor of FIG. 3A. FIG. 3C is a magnified view of the edge of the capacitor of FIG. 3A, showing more detail. Much of the description of FIGS. 1A-1D also apply to this embodiment, and only the differences are discussed below.

Referring first to FIG. 3A and FIG. 3C, the four conductive layers 140, 150, 160, 170 generally have the same width. In FIG. 3C, there is no non-overlapping surface area for any of the conductive layers. The dielectric buffer structures 251, 252, 253, 254 are all located above each other, and generally w4=w3=w2=w1. The thicknesses t1, t2, t3 of the insulator layers remain generally constant, and are not reduced.

Continuing, dielectric buffer structures 255 are also present in each conductive layer when an electrical contact/via passes through the conductive layer (see FIG. 3C for better detail). In addition, as illustrated here, a barrier layer 258 is also present within each via.

Referring now to the plan view of FIG. 3B, here, the two trenches 120 are illustrated as having a square shape. A dashed line indicates the surface area of the capacitor 102 upon the substrate 110. A dielectric buffer structure 254 is shown extending around the perimeter of a conductive layer 170. The electrical contacts/vias 241, 242, 243, 244 may also be located at any desirable location, and not only along the perimeter of the conductive layer. Each via is surrounded by a barrier layer 258 and a dielectric buffer structure 255. The contact pads 246, 247 are also indicated in dashed line.

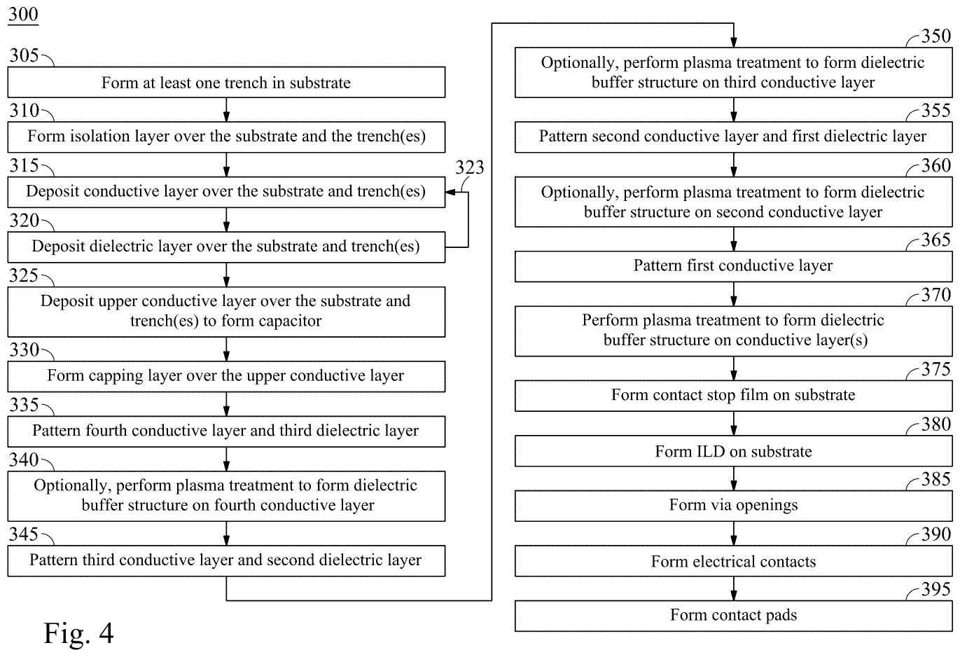

FIG. 4 is a flow chart illustrating a first method 300 for making a semiconducting substrate with a capacitor 102 such as that illustrated in FIGS. 1A-1D, in accordance with some embodiments. Some steps of the method are also illustrated in FIGS. 4-16. These figures provide different views for better understanding. While the method steps are discussed below in terms of forming a single capacitor, such discussion should also be broadly construed as applying to the formation of multiple capacitors concurrently. Other structures may also be concurrently formed. It is noted that not all steps described in the flow chart are required, and not all method steps are described in the flow chart.

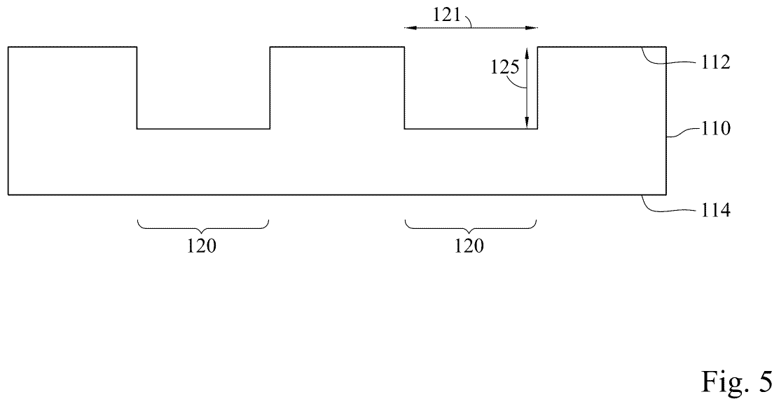

Referring first to FIG. 5, the method begins with a semiconducting substrate 110. Semiconductor materials can include silicon, for example in the form of crystalline Si. In alternative embodiments, the substrate can be made of other elementary semiconductors such as germanium, silicon carbide (SiC), silicon germanium, or silicon germanium carbide. The substrate may alternatively include a compound semiconductor such as gallium arsenide (GaAs), gallium phosphide, gallium carbide, indium arsenide (InAs), indium phosphide (InP), gallium arsenic phosphide, gallium indium phosphide, cadmium telluride, or cadmium sulfide. In particular embodiments, the substrate is silicon. The substrate 110 has an upper surface 112 and a lower surface 114, and has a thickness 115 between these two surfaces.

In step 305 of FIG. 4 and as illustrated in FIG. 5, at least one trench 120 is formed in the substrate. This may be done by patterning and etching. Each trench extends from the upper surface 112 into the substrate. Each trench may have any desired length, depth 125, and width 121.

The aspect ratio of a trench may be measured as the ratio of the trench depth 125 to the trench width 121. In some particular embodiments, the aspect ratio of each trench is from about 3 to about 15, and in more specific embodiments from about 11 to about 15. Other values and ranges for each of these measurements are also within the scope of this disclosure.

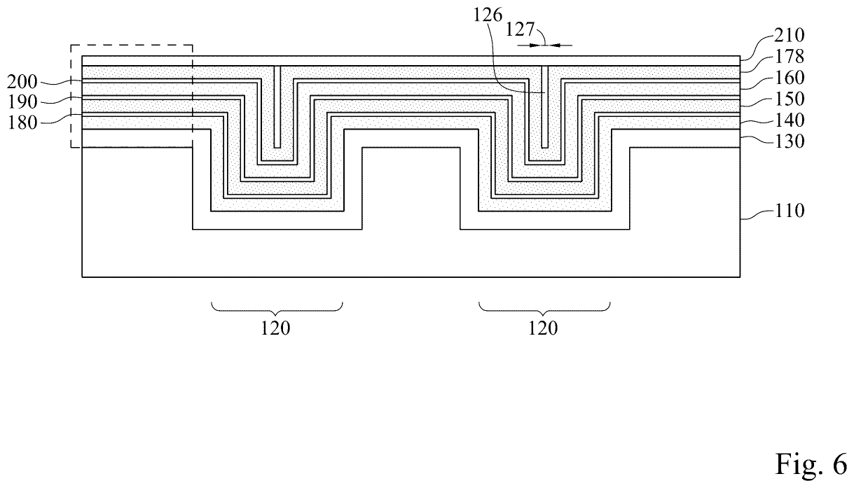

Next, in step 310 of FIG. 4 and as illustrated in FIG. 6, an isolation layer 130 is formed over the substrate 110 and the trench(es) 120. The isolation layer is a dielectric material, and can be formed by any suitable process, such as chemical vapor deposition (CVD), physical vapor deposition (PVD), atomic layer deposition (ALD), thermal oxidation, or other suitable methods. In some particular embodiments, the isolation layer is formed from silicon dioxide (SiO₂). This may be done, for example, by heating the exposed surfaces of the substrate in the presence of water or oxygen (O₂) which provides oxygen atoms that react with the silicon atoms in the substrate.

Continuing, the capacitor is then formed upon the isolation layer 130. As indicated in step 315 of FIG. 4 and as illustrated in FIG. 6, a conductive layer is deposited over the substrate 110 and the trench(es) 120. The conductive layer is a conformal layer that has a generally uniform thickness, and covers the exposed surfaces of the substrate and the trenches. Then, in step 320 of FIG. 4, an insulator layer is deposited over the substrate 110 and the trench(es) 120, and covers the conductive layer. The insulator layer is a conformal layer that has a generally uniform thickness, and also covers the exposed surfaces of the substrate and the trenches. These two steps are repeated, as indicated by arrow 323, to form as many layers as desired. Referring to FIG. 6, conductive layers 140, 150, 160 and insulator layers 180, 190, 200 are thus formed. These steps may be performed by appropriate methods such as CVD, PVD, sputtering, etc.

Then, in step 325 of FIG. 4, an upper conductive layer 178 is deposited over the substrate 110 and the trench(es) 120 to complete the capacitor. It is noted that cavities 126 can remain over each trench 120. This may be done by appropriate control of the trench width and the thicknesses of the various conductive layers and insulator layers. In some embodiments, the width 127 of each cavity may be from about 10 nanometers to about 50 nanometers, although other values and ranges are within the scope of the present disclosure.

It is noted that in some particular embodiments, all conductive layers 140, 150, 160, 170 are made of the same material (for example, TiN) and all insulator layers 180, 190, 200 of the capacitor are made of the same material. In other particular embodiments, alternating conductive layers are made of the same material, or in other words adjacent conductive layers are made of different materials.

Then, in step 330 of FIG. 4 and as illustrated in FIG. 6, a capping layer 210 is formed over the upper conductive layer 178. The capping layer is generally a dielectric material, such as silicon dioxide (SiO₂). The capping layer may be formed by CVD, PVD, ALD, or other suitable deposition method. If desired, the capping layer may be planarized.

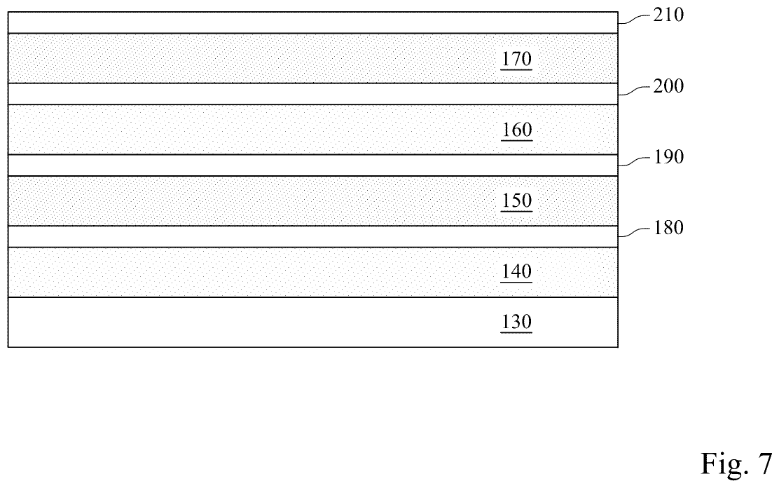

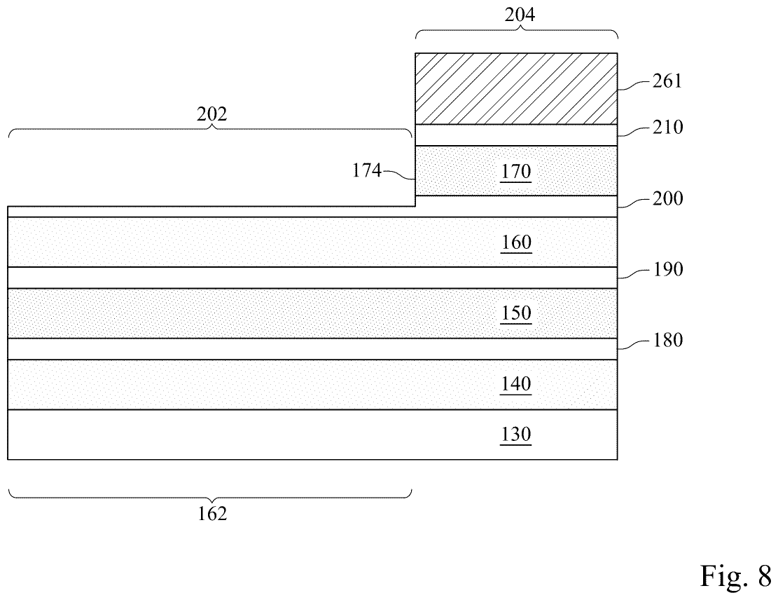

FIG. 7 is a magnified view of the edges as indicated in the dashed box of FIG. 6. Continuing, then, in step 335 of FIG. 4 and as illustrated in FIG. 8, the fourth conductive layer 170 and the third insulator layer 200 are patterned. The capping layer 210 is also patterned. As illustrated here, a first mask 261, such as photoresist, has been applied and the exposed surface area is then etched. The side 174 of the fourth conductive layer is thus exposed. A non-overlapping upper surface area 162 of the third conductive layer is created. The outer portion 202 of the third insulator layer 200 is thinned compared to its central portion 204.

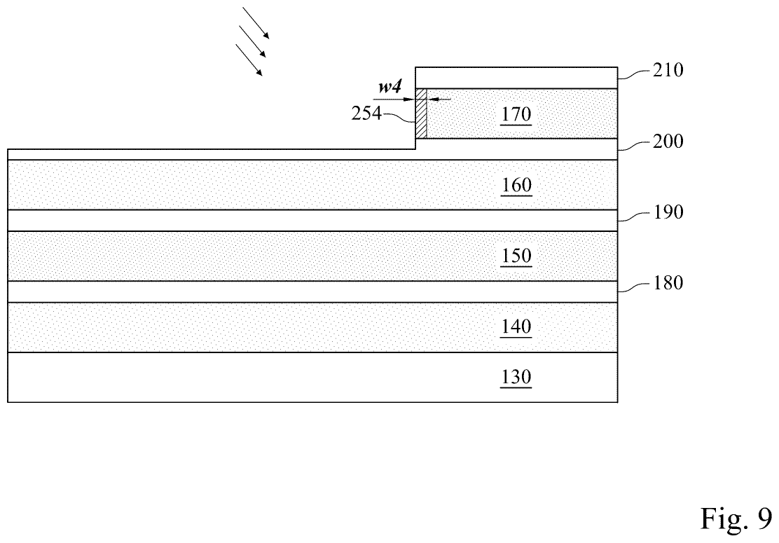

In optional step 340 of FIG. 4 and as illustrated in FIG. 9, after the first mask is removed, a plasma treatment is performed to form a dielectric buffer structure 254 in the fourth conductive layer. This oxidizes the exposed conductive material. The resulting dielectric buffer structure 254 has a width w4. It is emphasized that this step is optional, and does not need to be performed.

The plasma treatment is a process in which a plasma is formed from an oxygen-containing process gas, and could also be referred to as a “gas bump”. The ions attack the exposed sides of the fourth conductive layer and react with the material of the conductive layer to form the dielectric buffer structure. The term “oxygen-containing”, when used in reference to the process gas, means the process gas is a compound that contains one or more oxygen atoms, and does not specifically refer to the diatomic gas O₂. Examples of oxygen-containing process gases may include nitrogen dioxide (N₂O), diatomic oxygen (O₂), and ozone (O₃).

In some embodiments, the flow rate of the oxygen-containing process gas may be from about 8,000 standard cubic centimeters per minute (SCCM) to about 15,000 SCCM. In some embodiments, the plasma treatment may be performed at an RF power of about 300 watts to about 500 watts. In some embodiments, the plasma treatment may be performed for a time period of about 5 seconds to about 50 seconds. However, other ranges and values for each of these parameters are within the scope of the present disclosure.

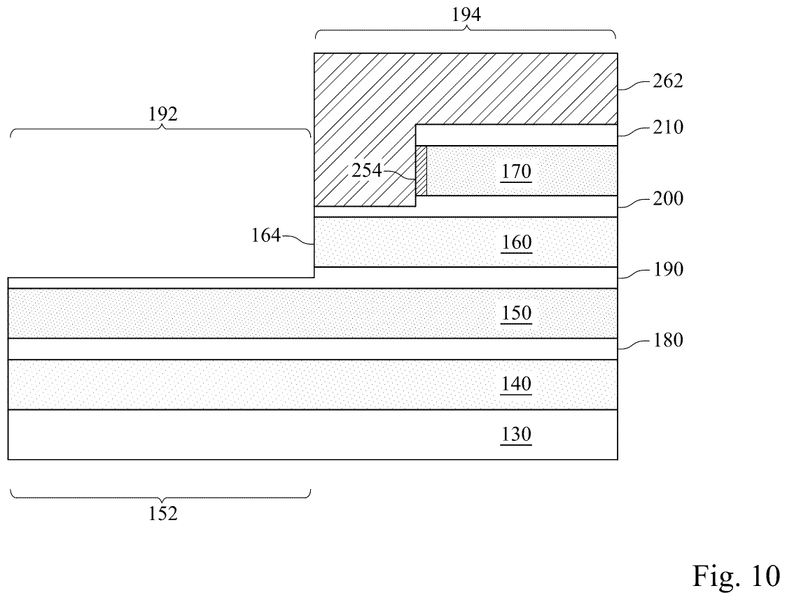

Next, in step 345 of FIG. 4 and as illustrated in FIG. 10, the third conductive layer 160 and the second insulator layer 190 are patterned. As illustrated here, a second mask 262 has been applied and the exposed surface area is then etched. The mask covers the capping layer 210, the fourth conductive layer 170, and the third insulator layer 200. The side 164 of the third conductive layer is thus exposed. A non-overlapping upper surface area 152 of the second conductive layer is created. The outer portion 192 of the second insulator layer 190 is thinned compared to its central portion 194.

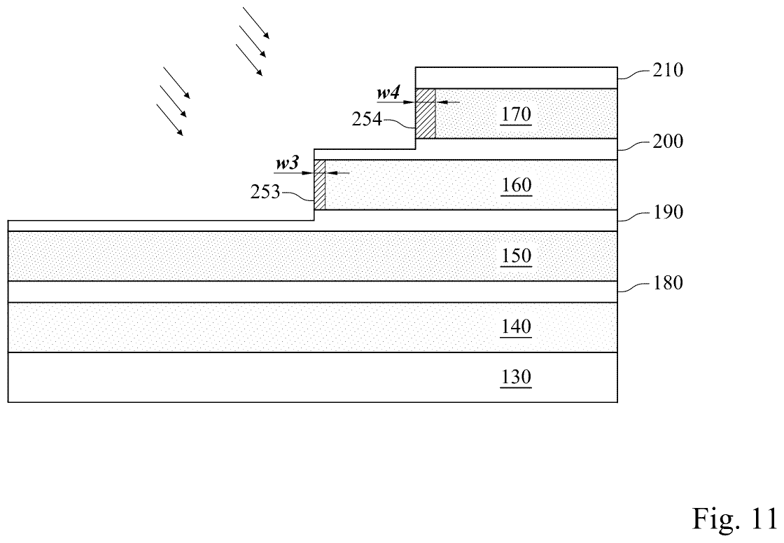

In optional step 350 of FIG. 4 and as illustrated in FIG. 11, after the second mask is removed, a plasma treatment is performed to form a dielectric buffer structure 253 in the third conductive layer. The resulting dielectric buffer structure 253 has a width w3. It is emphasized that this step is optional, and does not need to be performed. It is noted that because the side of the fourth conductive layer is also exposed, the width w4 of the dielectric buffer structure 254 will increase.

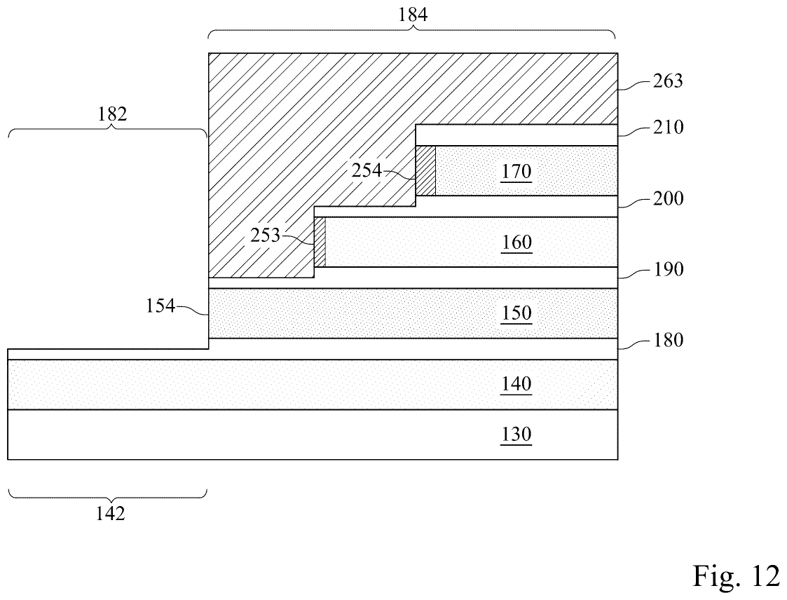

In step 355 of FIG. 4 and as illustrated in FIG. 12, the second conductive layer 150 and the first insulator layer 180 are patterned. As illustrated here, a third mask 263 has been applied and the exposed surface area is then etched. The mask covers the capping layer 210, the fourth conductive layer 170, the third insulator layer 200, the third conductive layer 160, and the second insulator layer 190. The side 154 of the second conductive layer is thus exposed. A non-overlapping upper surface area 142 of the first conductive layer is created. The outer portion 182 of the first insulator layer 180 is thinned compared to its central portion 184.

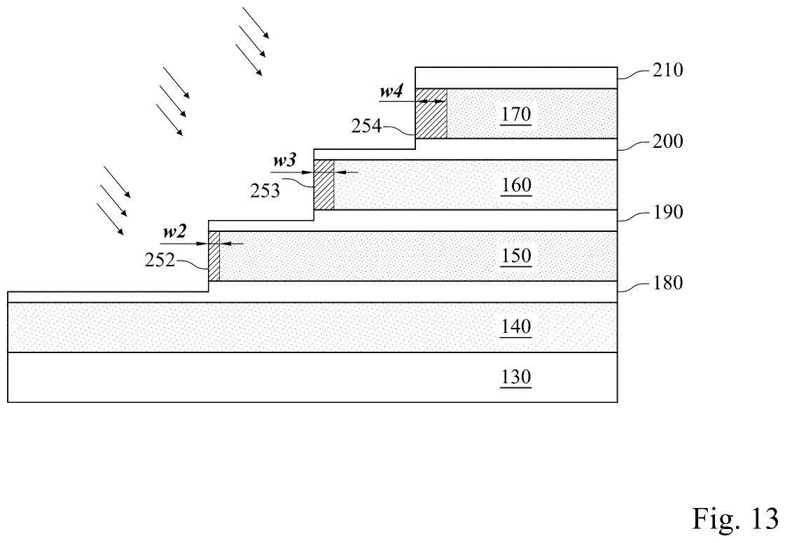

In optional step 350 of FIG. 4 and as illustrated in FIG. 13, after the third mask is removed, a plasma treatment is performed to form a dielectric buffer structure 252 in the second conductive layer. The resulting dielectric buffer structure 252 has a width w2. It is emphasized that this step is optional, and does not need to be performed. It is noted that because the sides of the third and fourth conductive layers are also exposed, the widths w3 and w4 of the respective dielectric buffer structures 253, 254 will increase.

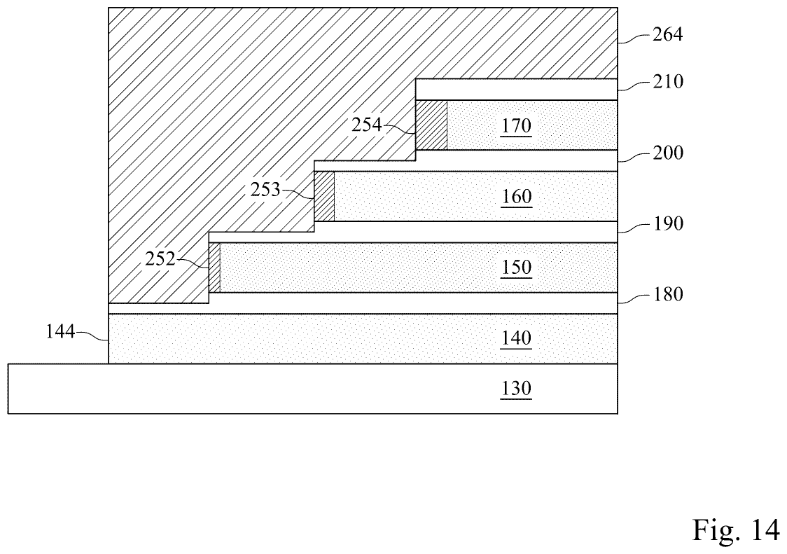

In step 365 of FIG. 4 and as illustrated in FIG. 14, the first conductive layer 140 is patterned. As illustrated here, a fourth mask 264 has been applied and the exposed surface area is then etched. The mask covers the capping layer 210, the fourth conductive layer 170, the third insulator layer 200, the third conductive layer 160, the second insulator layer 190, the second conductive layer 150, and the first insulator layer 180. The side 144 of the first conductive layer is thus exposed. A portion of the upper surface of the isolation layer 130 is also exposed.

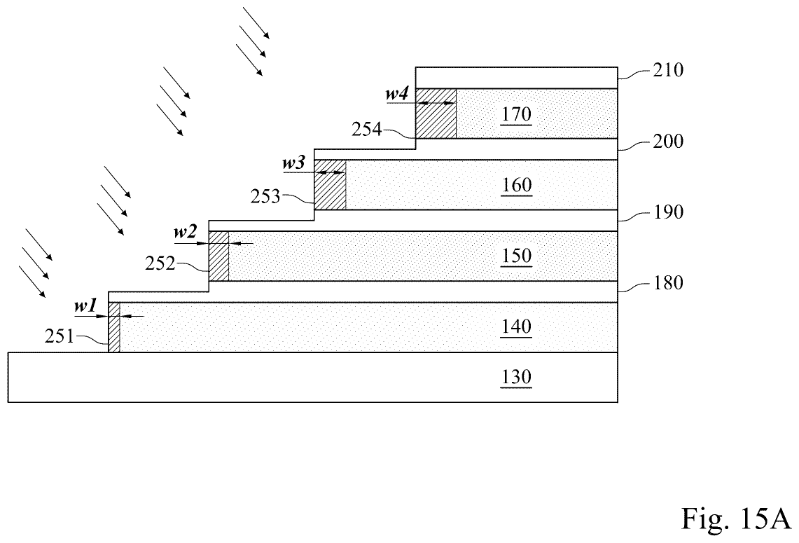

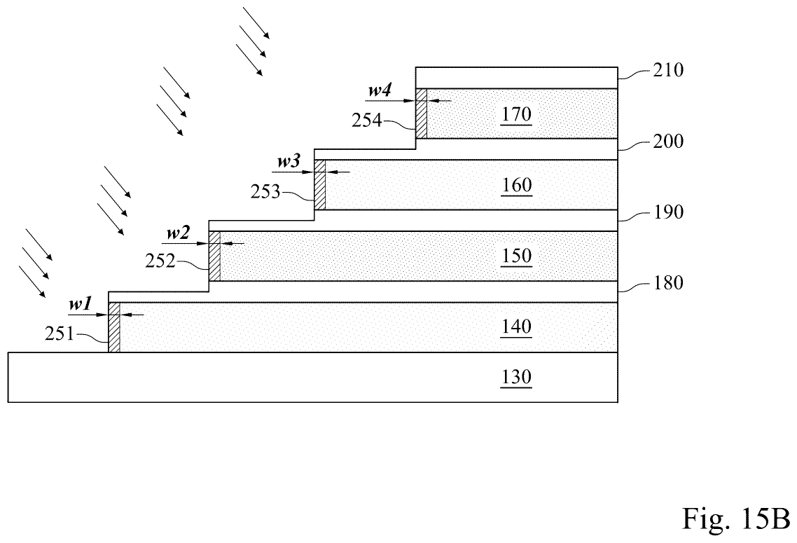

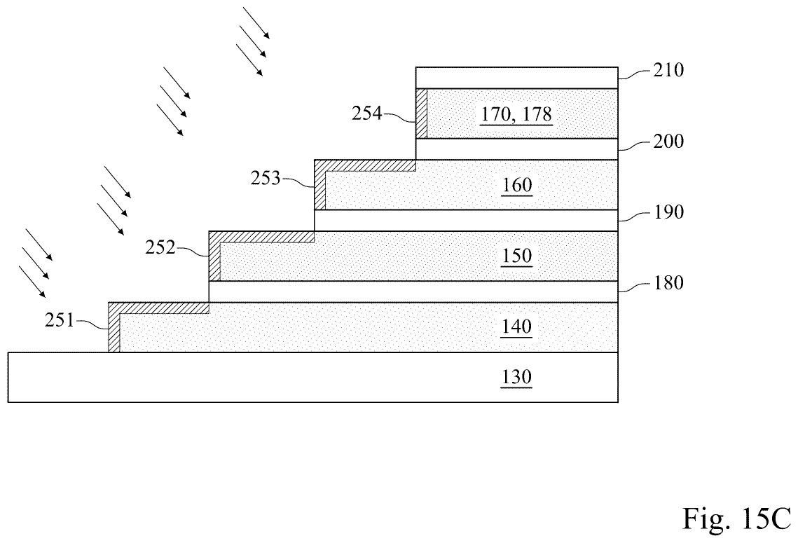

In step 370 of FIG. 4 and as illustrated in FIG. 15A, a plasma treatment is performed to form a dielectric buffer structure 251 in the first conductive layer. The resulting dielectric buffer structure 251 has a width w1. Again, because the sides of the other three conductive layers are also exposed, the widths w2, w3, and w4 of the dielectric buffer structures 252, 253, 254 will also increase. As illustrated in FIG. 15A, optional plasma treatment steps 340, 350, 360 have been performed. As a result, w4>w3>w2>w1. It is noted the isolation layer 130 generally does not react with the plasma treatment, and remains an electrical insulator.

In the embodiment illustrated in FIG. 15B, optional plasma treatment steps 340, 350, 360 were not performed. As a result, the dielectric buffer structures 251, 252, 253, 254 in each conductive layer are formed in step 370. As a result, w4=w3=w2=w1.

In the embodiments of FIG. 15A and FIG. 15B, the thinned outer portion of each insulator layer was sufficiently thick enough to act as a mask during plasma treatment. In the embodiment illustrated in FIG. 15C, the insulator layer was completely removed from each non-overlapping upper surface area. As a result, the three dielectric buffer structures 251, 252, 253 (not in the upper conductive layer 178) also include an upper portion.

In an alternative method, the dielectric buffer structures 251, 252, 253, 254 could be formed by ion implantation or other similar process, instead of by plasma treatment. Briefly, an ion implanter is used to implant oxygen ions into the conductive layers. An ion implanter generally includes an ion source, a beam line, and a process chamber. The ion source produces the desired ions (here, oxygen (O²⁻)). The beam line organizes the ions into a beam having high purity in terms of ion mass, energy, and species. A mask, such as a patterned photoresist layer or a hard mask layer, is used to expose desired regions of the conductive layers. The ion beam is then used to irradiate the semiconducting wafer substrate in a process chamber. The ion beam strikes the exposed regions and the ions can be implanted into the conductive layer to form the dielectric buffer structures.

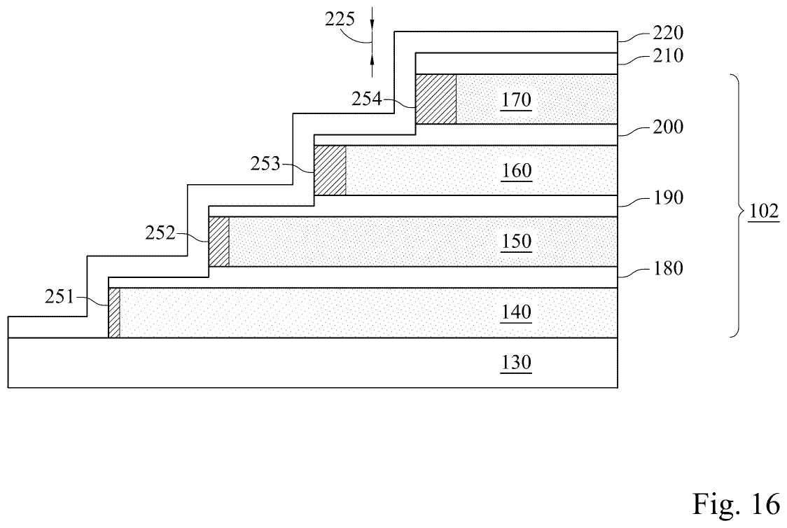

In step 375 of FIG. 4 and as illustrated in FIG. 16, a contact stop layer 220 is conformally formed upon the substrate 110 and over the capacitor 102. The contact stop layer has a generally uniform thickness, and may be formed by appropriate processes such as CVD or ALD. The contact stop layer is a dielectric material, and can be the same or different material from the capping layer 210. In particular embodiments, the contact stop layer is formed from silicon nitride (SiN). In particular embodiments, the thickness 225 of the contact stop layer is from about 300 angstroms to about 1,000 angstroms, although other values and ranges are within the scope of the present disclosure.

Next, in step 380 of FIG. 4 and referring to FIG. 1A, the ILD layer 230 is formed on the substrate and over the capacitor 102. The ILD layer is a dielectric material and may be formed by appropriate processes such as CVD.

Then, in step 385 of FIG. 4, via openings are formed. The via openings extend through the ILD layer 230 and insulator layers to contact the four conductive layers 140, 150, 160, 170. This may be done by appropriate patterning and etching.

Subsequently, in step 390 of FIG. 4, electrical contacts or vias 241, 242, 243, 244 are formed by filling the via openings with an electrically conductive material. Such materials may include metals or metal alloys such as tungsten (W), titanium (Ti), or tantalum (Ta). This may be done by appropriate deposition processes. Planarization may be performed to remove excess material from the ILD.

Finally, in step 395 of FIG. 4, contact pads 246, 247 are formed. This may be done by appropriate deposition and patterning processes. The contact pads are electrically conductive, and connect to appropriate electrical contacts and conductive layers so as to obtain the electrical diagram of FIG. 2. The resulting structure is shown in FIG. 1A.

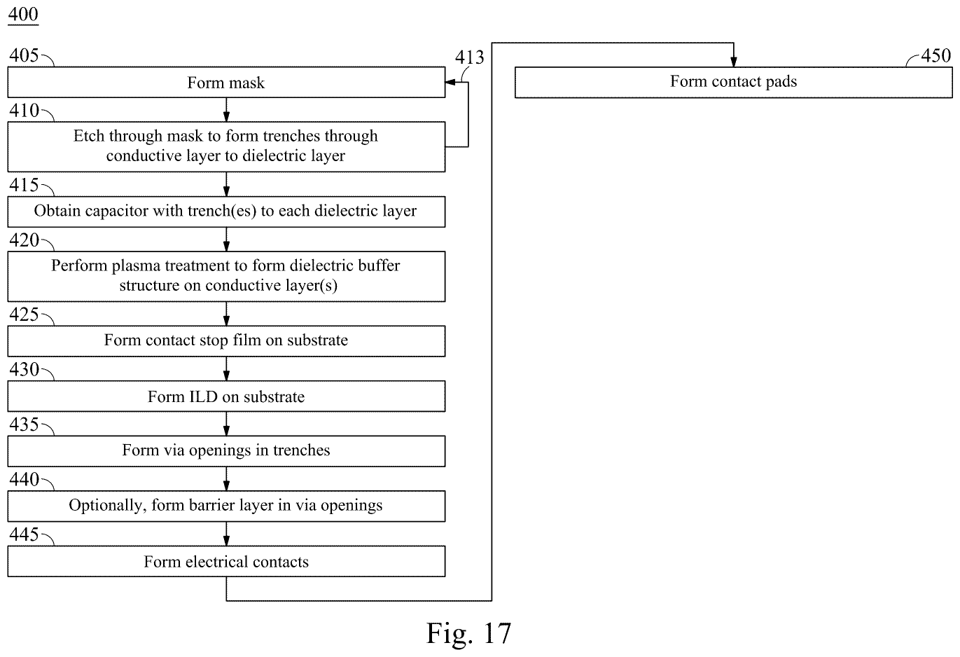

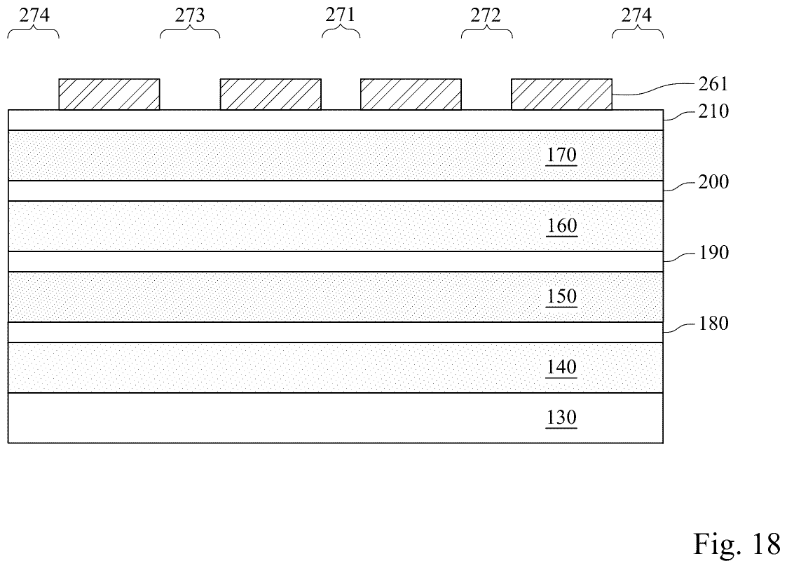

FIG. 17 is a flow chart illustrating a second method 400 for making a semiconducting substrate with a capacitor 102 such as that illustrated in FIGS. 3A-3E, in accordance with some embodiments. Some steps of the method are also illustrated in FIGS. 18-31. These figures provide different views for better understanding. While the method steps are discussed below in terms of forming a single capacitor, such discussion should also be broadly construed as applying to the formation of multiple capacitors concurrently. Other structures may also be concurrently formed. It is noted that not all steps described in the flow chart are required, and not all method steps are described in the flow chart.

FIG. 18 is a simplified view of the four conductive layers 140, 150, 160, 170 and the three insulator layers 180, 190, 200 with the capping layer 210 and upon the isolation layer 130. The trenches are not illustrated here. This structure may be formed as described in steps 305-330 of FIG. 4.

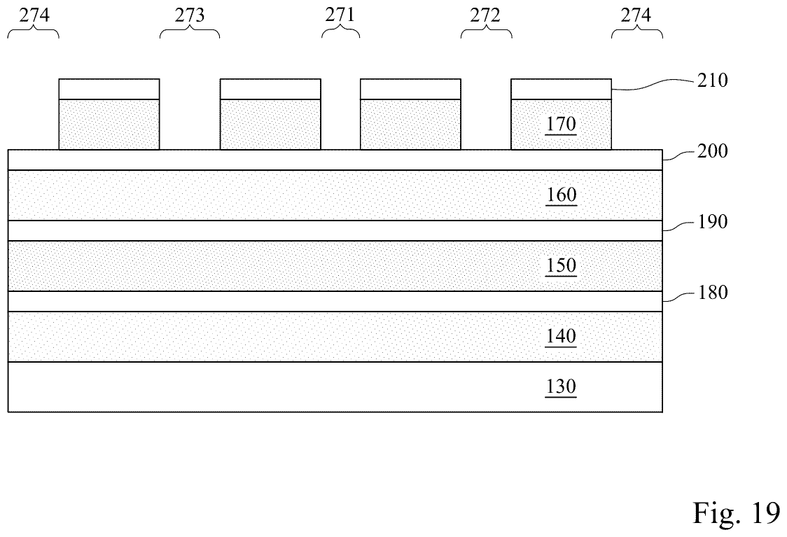

Continuing, in step 405 of FIG. 17 and as illustrated in FIG. 18, a first mask 261 is formed upon the substrate. As indicated here, the first mask forms three internal trenches 271, 272, 273 which will be present over the capacitor. Two external trenches 274 are included which will define the edges of the capacitor. Then, in step 410 of FIG. 17 and as illustrated in FIG. 19, etching is performed to form trenches through a conductive layer to an insulator layer. Here, the etching is performed through the capping layer 210 and the fourth conductive layer 170 down to the third insulator layer 200. These two steps are repeated, as indicated by arrow 413, in order to form via openings down to each conductive layer.

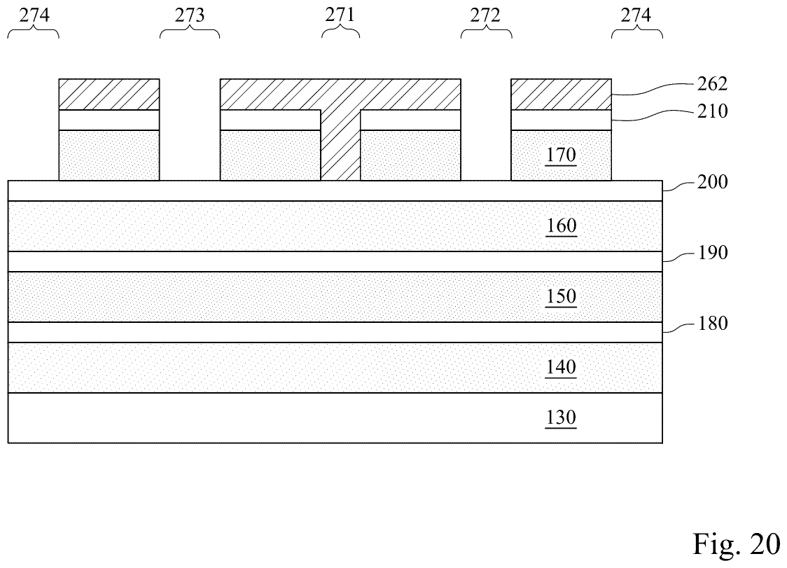

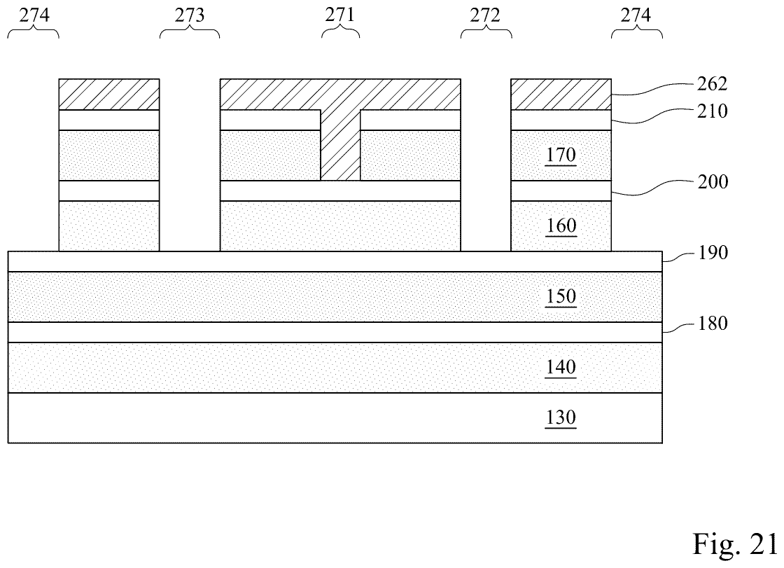

FIG. 20 illustrates the second mask 262, which also fills internal trench 271 that extends to the third insulator layer 200. As seen in FIG. 21, the next etching step extends internal trenches 272, 273 and external trenches 274 down to the second insulator layer 190.

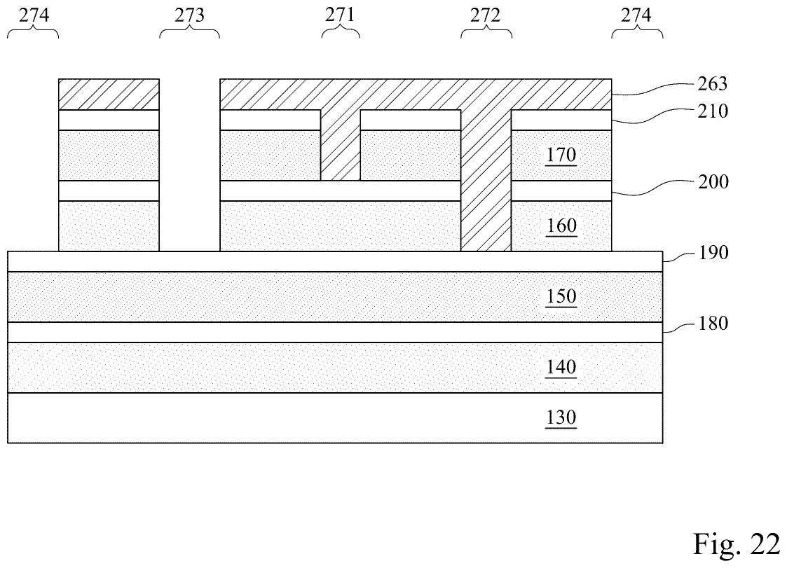

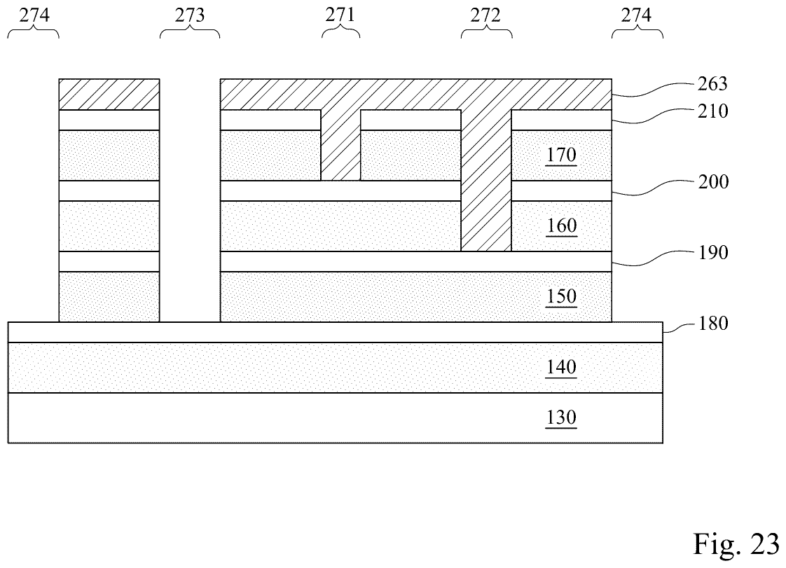

FIG. 22 illustrates the third mask 263, which also fills internal trench 272 that extends to the second insulator layer 190. As seen in FIG. 23, the next etching step extends internal trench 273 and external trenches 274 down to the first insulator layer 180.

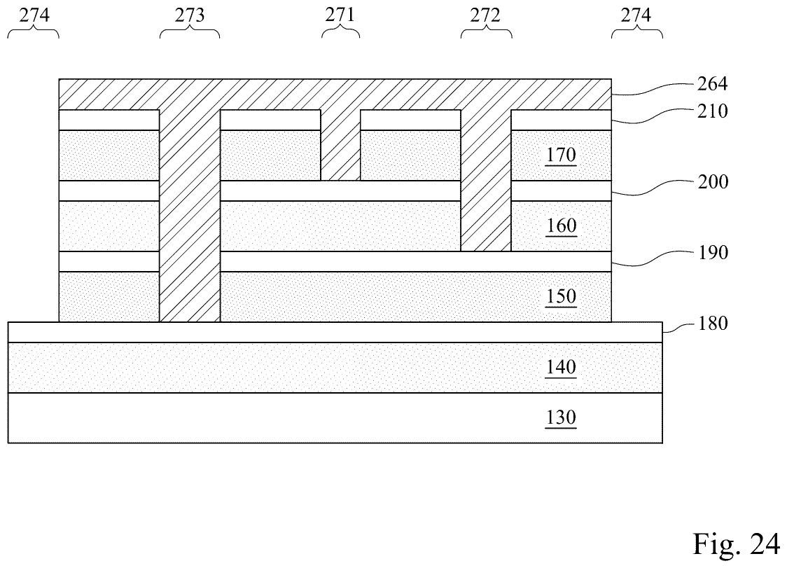

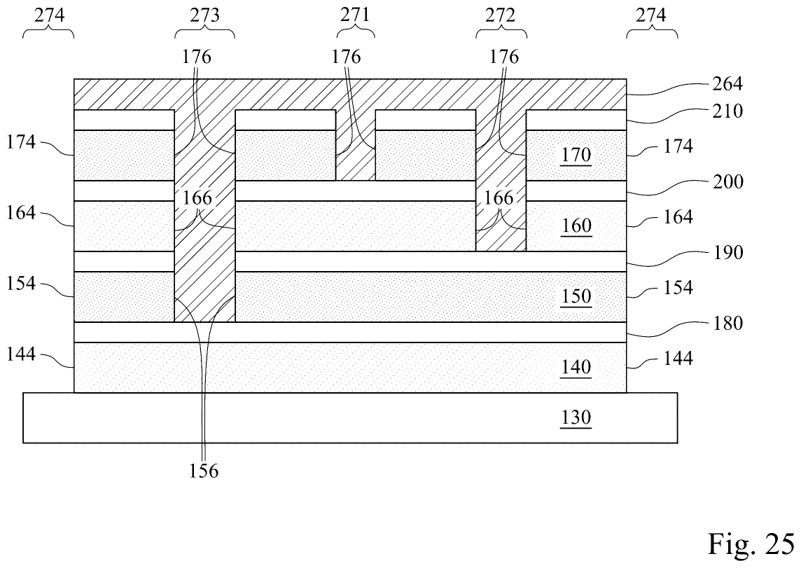

FIG. 24 illustrates the fourth mask 264, which also fills internal trench 273 that extends to the first insulator layer 180. As seen in FIG. 25, the next etching step extends the external trenches 274 down to the isolation layer 130. As indicated in step 415 of FIG. 17, then, a capacitor with trenches 271, 272, 273 to each insulator layer 200, 190, 180 respectively within the capacitor is obtained.

Referring now to FIG. 25, the external sides 144, 154, 164, 174 of each conductive layer are exposed along the external trenches 274. In addition, the internal sides 156, 166, 176 of each conductive layer are also exposed along the internal trenches 271, 272, 273.

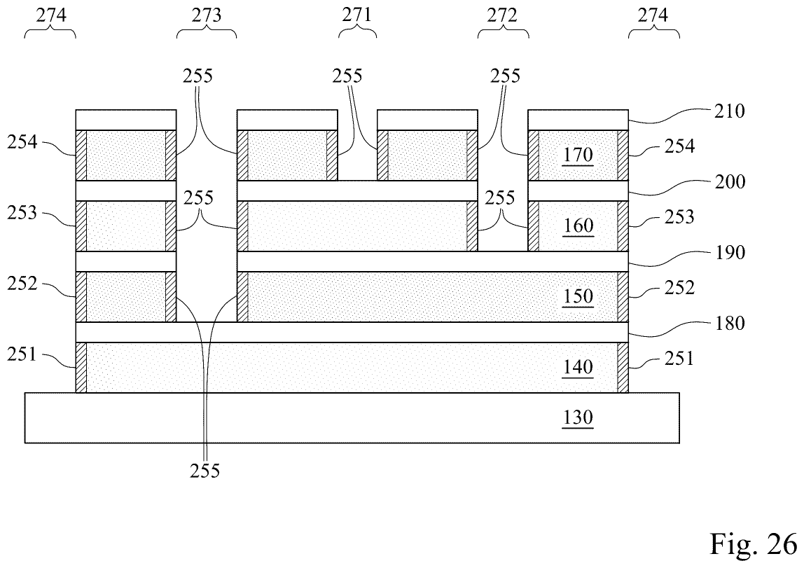

In step 420 of FIG. 17 and as illustrated in FIG. 26, after the fourth mask is removed, plasma treatment is performed to form one or more dielectric buffer structures on one or more exposed sides of one or more conductive layer. Put another way, at least one dielectric buffer structure is formed on an exposed side of at least one conductive layer. This may be done as previously described. As illustrated in FIG. 26, external dielectric buffer structures 251, 252, 253, 254 are formed in each conductive layer 140, 150, 160, 170. Internal dielectric buffer structures 255 are also formed in all conductive layers 150, 160, 170 but the first conductive layer 140 which is the lowest conductive layer. Again, as an alternative, ion implantation could be used to form the dielectric buffer structures if desired.

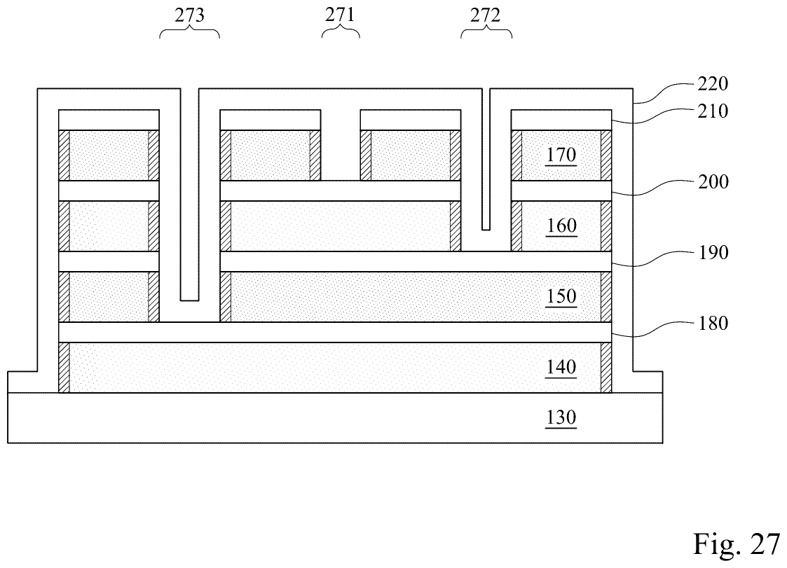

In step 425 of FIG. 17 and as illustrated in FIG. 27, a contact stop layer 220 is conformally formed upon the substrate 110 and over the capacitor. The contact stop layer has a generally uniform thickness, and may be formed by appropriate processes such as CVD or ALD. As illustrated here, the contact stop layer 220 is also formed upon the internal surfaces of the internal trenches 271, 272, 273 and can fill the internal trenches, as illustrated here with internal trench 271.

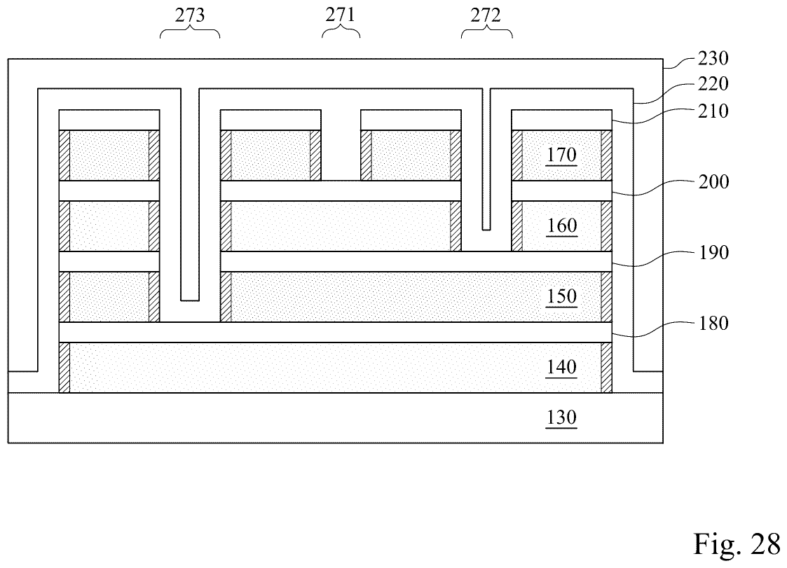

Next, in step 430 of FIG. 17 and as illustrated in FIG. 28, the ILD layer 230 is formed on the substrate and over the capacitor 102. The ILD layer is a dielectric material and may be formed by appropriate processes such as CVD. The ILD layer can also fill the internal trenches.

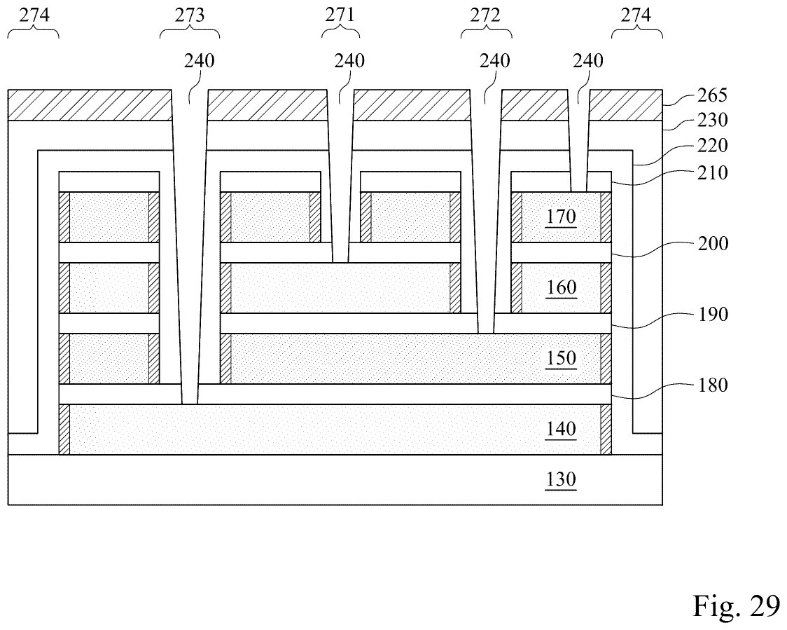

Then, in step 435 of FIG. 17 and as illustrated in FIG. 29, via openings 240 are formed. A mask 265 is applied and patterned, and etching is performed. The via openings extend through the ILD layer 230, the contact stop layer 220, the capping layer 210, and the various insulator layers as needed to contact the four conductive layers 140, 150, 160, 170. As illustrated here, three of the via openings are formed in the internal trenches 271, 272, 273.

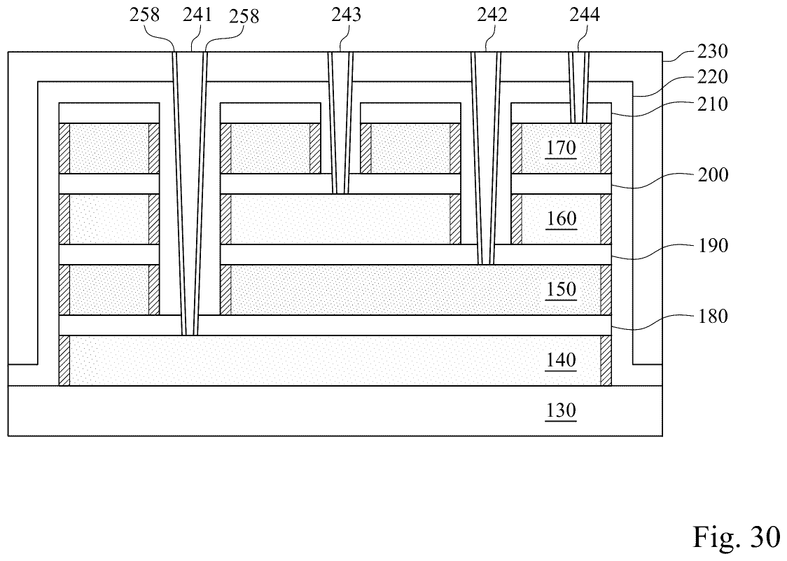

In optional step 440 of FIG. 17 and as illustrated in FIG. 30, a barrier layer 258 may be formed in the via openings 240. The barrier layer reduces or prevents migration of metal from the via into the capacitor. In some embodiments, the barrier layer is formed from Ta/TaN or Ni. The barrier layer is optional, and is not required.

Subsequently, in step 445 of FIG. 17, electrical contacts or vias 241, 242, 243, 244 are formed by filling the via openings with an electrically conductive material. Such materials may include metals or metal alloys such as tungsten (W), titanium (Ti), or tantalum (Ta) or Copper (Cu). This may be done by appropriate deposition processes. Planarization may be performed to remove excess material from the ILD.

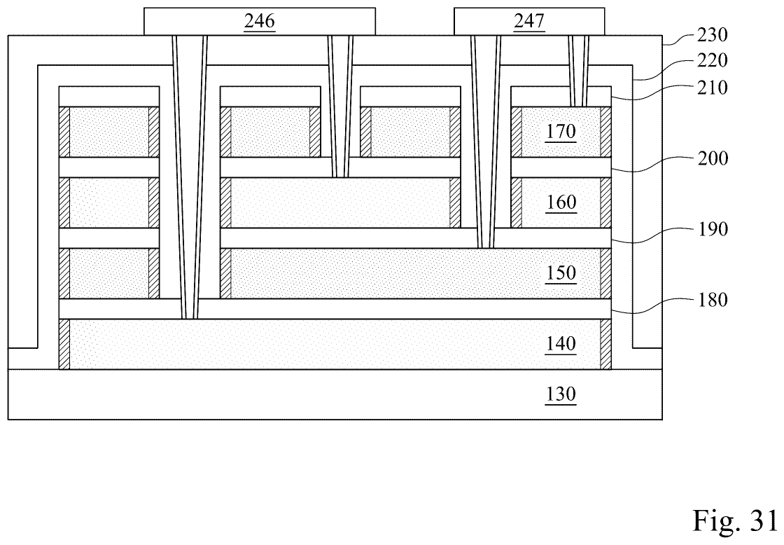

Finally, in step 450 of FIG. 17 and as illustrated in FIG. 31, contact pads 246, 247 are formed. This may be done by appropriate deposition and patterning processes. The contact pads are electrically conductive, and connect to appropriate electrical contacts and conductive layers so as to obtain the electrical diagram of FIG. 2. The resulting structure is shown in FIG. 3A.

It is noted the multiple plasma treatments described in the method of FIG. 2, resulting in dielectric buffer structures of different widths in different conductive layers, may also be applied to the aligned edge capacitor of FIG. 3A if desired. It is also noted that the internal vias formed in the method of FIG. 17 may also be formed in the stepped edge capacitor of FIG. 1A instead of along the perimeter, if desired.

Non-limiting examples of electrically insulating materials (i.e. dielectric materials) which can be used in the present disclosure may include oxides such as silicon dioxide (SiO₂), aluminum oxide (Al₂O₃), tantalum oxide (Ta₂O₅), zirconium dioxide (ZrO₂), or hafnium dioxide (HfO₂); nitrides such as silicon carbon nitride (SiCN), silicon nitride (SiN), hafnium oxynitride (HfOₓN_{y}), zirconium oxynitride (ZrOₓN_{y}), where 0<x, y, ≤1; silicates like hafnium silicates (HfSiₓO_{y}) or zirconium silicates (ZrSiₓO_{y}), where 0<x, y, ≤1; polysilicon, phosphosilicate glass (PSG), fluorosilicate glass (FSG), undoped silicate glass (USG), high-stress undoped silicate glass (HSUSG), borosilicate glass (BSG), a high-k dielectric material, or a low-k dielectric material.

It is noted that certain related steps are not expressly described in the discussion above. For example, a pattern/structure may be formed in a given layer by applying a photoresist layer, patterning the photoresist layer, developing the photoresist layer, and then etching.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the photoresist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90 °C to about 110 °C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern. One example of a common developer is aqueous tetramethylammonium hydroxide (TMAH). Generally, any suitable developer may be used. Sometimes, a post develop bake or “hard bake” may be performed to stabilize the photoresist pattern after development, for optimum performance in subsequent steps.

Continuing, portions of the layer below the patterned photoresist layer are now exposed. Etching transfers the photoresist pattern to the layer below the patterned photoresist layer. After use, the patterned photoresist layer can be removed, for example, using various solvents such as N-methyl-pyrrolidone (NMP) or alkaline media or other strippers at elevated temperatures, or by dry etching using oxygen plasma.

Generally, any etching step used herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), nitrogen trifluoride (NF₃), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

Planarization of a surface may be performed, for example, using a chemical mechanical polishing (CMP) process. Generally, CMP is performed using a rotating platen to which a polishing pad is attached. The substrate is attached to a rotating carrier. A slurry or solution containing various chemicals and abrasives is dispensed onto the polishing pad or the wafer substrate. During polishing, both the polishing pad and the carrier rotate, and this induces mechanical and chemical effects on the surface of the wafer substrate and/or the top layer thereon, removing undesired materials and creating a highly level surface. A post-CMP cleaning step is then carried out using rotating scrubber brushes along with a washing fluid to clean one or both sides of the wafer substrate.

Semiconductor devices containing the capacitors illustrated herein may be used in various applications. Those semiconductor devices might include central processing units (CPUs), graphics processing units (GPUs), graphics integrated circuits, and/or server or power management integrated circuits. Various devices might include those such as image signal processors (ISP), which can be combined with CMOS image sensors; or global shutters for high speed capture in a camera or monitor. Other potential applications might include BCD (Bipolar-CMOS-DMOS) circuits for driving discrete high voltage components; drivers for LCD, OLED, AMOLED, or QLED display panels; image sensors that can be used in systems such as mobile telephones, facial recognition systems, or as motion sensors for automotive applications, security applications, energy efficiency, etc.; power management devices that control the flow and direction of electrical power; and/or artificial intelligence applications.

The capacitors of the present disclosure have several advantages. The presence of the dielectric buffer structure reduces leakage current. Capacitance is thus increased. Current process tools can be used for the manufacturing process. Deep trenches can release stress which may arise due to, for example, the differences in the coefficient of expansion between different layers or due to the heterogeneous distribution of material within layers.

Some embodiments of the present disclosure thus relate to methods of reducing leakage current in a capacitor. Very generally, a dielectric buffer structure is formed from exposed sides of at least one conductive layer of the capacitor. The dielectric buffer structure can be formed, for example, by plasma treatment using an oxygen-containing process gas. They could also be formed by ion implantation of oxygen ions.

Other embodiments disclosed herein relate to capacitors with a dielectric buffer structure. The capacitor is formed from a plurality of conductive layers stacked over each other. At least a first conductive layer and a second conductive layer over the first conductive layer are present, with at least one of the conductive layers having a dielectric buffer structure along exposed sides of the conductive layer. A first insulator layer is present between the first conductive layer and the second conductive layer.

Also described in various embodiments herein are methods of making a multi-layer capacitor with a dielectric buffer structure on the exposed sides of the conductive layers. At least one trench is formed in a substrate. An isolation layer is formed over the substrate and the at least one trench. Alternate deposition of at least one conductive layer and at least one insulator layer over the substrate and the at least one trench is performed as many times as desired, ending with depositing an upper conductive layer. As a result, a capacitor is formed. A capping layer is then formed over the upper conductive layer of the capacitor. One or more dielectric buffer structures are formed on exposed sides of each conductive layer. A contact stop layer is formed over an upper surface and sides of the capacitor. Electrical contacts are then formed to each conductive layer of the capacitor.

The present disclosure also relates in various embodiments to other methods of making multi-layer capacitors with dielectric buffer structures on exposed external and internal sides (e.g. next to trenches or via openings).

At least one trench is formed in a substrate. An isolation layer is formed over the substrate and the at least one trench. Alternate deposition of at least one conductive layer and at least one insulator layer over the substrate and the at least one trench is performed as many times as desired, ending with depositing an upper conductive layer. As a result, a capacitor is formed. A capping layer is then formed over the upper conductive layer of the capacitor. Internal trenches are formed to each insulator layer of the capacitor, which exposes internal sides of all conductive layers but the bottom conductive layer of the capacitor. One or more dielectric buffer structures are then formed on the exposed sides of each conductive layer, including the outer sides and the internal sides of the internal trenches. A contact stop layer and an ILD layer are formed over an upper surface and sides of the capacitor. Via openings are then formed to each conductive layer. A barrier layer may be optionally applied in each via opening. Electrical contacts are then formed to each conductive layer of the capacitor by filling the via openings.

Some further embodiments of the present disclosure also relate to semiconductor devices including such capacitors. Those semiconductor devices may include CPUs, GPUs, and power management integrated circuits. Devices incorporating such semiconductor devices are also disclosed.

The methods, systems, and devices of the present disclosure are further illustrated in the following non-limiting working example, it being understood that the example is intended to be illustrative only and that the disclosure is not intended to be limited to the materials, conditions, process parameters and the like recited herein.

### EXAMPLES

An electrically conductive titanium nitride layer was exposed to an N₂O plasma treatment to form a dielectric buffer structure. Species analysis of the TiN layer and the dielectric buffer structure was performed, and the following results of Table A were obtained:

TABLE A

| | Conductive TiN layer | Dielectric Buffer Structure |
|---|---|---|
| Ti (mole %) | 52.2 | 36 |
| N (mole %) | 43 | 4.5 |
| O (mole %) | 2 | 59 |

The TiN layer was electrically conductive, while the buffer structure containing high amounts of oxygen was an electrical insulator.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for reducing current leakage in a capacitor of a semiconductor device, comprising:
forming a capacitor by depositing at least a first conductive layer, a first insulator layer, and a second conductive layer over a substrate;
forming a dielectric buffer structure on one or more exposed sides of at least one of the conductive layers of the capacitor.

2. The method of claim 1, wherein the dielectric buffer structure is formed by oxidizing the one or more exposed sides of the at least one conductive layer.

3. The method of claim 2, wherein oxidation is performed by (i) plasma treatment in the presence of an oxygen-containing process gas; or by (ii) ion implantation.

4. The method of claim 3, wherein the oxygen-containing process gas is O₂, N₂O, or O₃.

5. The method of claim 3, wherein the oxygen-containing process gas is provided at a flow rate of about 8,000 sccm to about 15,000 sccm.

6. The method of claim 3, wherein the plasma treatment is performed at an RF power of about 300 watts to about 500 watts.

7. The method of claim 3, wherein the plasma treatment is performed at a pressure of about 0.5 mTorr to about 2.5 mTorr.

8. The method of claim 3, wherein the plasma treatment is performed for a time period of about 5 seconds to about 50 seconds.

9. The method of claim 1, wherein the dielectric buffer structure has a width of about 5 nm to about 50 nm.

10. The method of claim 1, wherein the at least one conductive plate is made of TiN, TaN, or polysilicon.

11. The method of claim 1, wherein the dielectric buffer structure also extends along an upper surface of the at least one conductive layer.

12. A capacitor, comprising:
a plurality of conductive layers on a semiconductor substrate that are stacked over each other including at least a first conductive layer and a second conductive layer over the first conductive layer, at least one of the conductive layers having a dielectric buffer structure along exposed sides of the conductive layer; and
a first insulator layer between the first conductive layer and the second conductive layer.

13. The capacitor of claim 12, wherein each conductive layer has a non-overlapping upper surface area.

14. The capacitor of claim 13, wherein an outer portion of the first insulator layer covering the non-overlapping upper surface area of the first conductive layer is thinner than a central portion of the first insulator layer.

15. The capacitor of claim 13, wherein the first insulator layer does not cover the non-overlapping upper surface area of the first conductive layer; and
the dielectric buffer structure also extends along the non-overlapping upper surface area of the first conductive layer.

16. The capacitor of claim 12, wherein a width of the dielectric buffer structure of the second conductive layer is greater than a width of the dielectric buffer structure of the first conductive layer.

17. The capacitor of claim 12, wherein the first conductive layer, the first insulator layer, and the second conductive layer extend along a surface of a substrate and into a trench in the substrate.

18. The capacitor of claim 12, wherein the plurality of conductive layers further comprises:
a third conductive layer over the second conductive layer; and
a fourth conductive layer over the third conductive layer;
a second insulator layer between the second conductive layer and the third conductive layer;
a third insulator layer between the third conductive layer and the fourth conductive layer;
electrical contacts connecting the first conductive layer and the third conductive layer to a first contact pad; and
electrical contacts connecting the second conductive layer and the fourth conductive layer to a second contact pad.

19. A method for making a capacitor, comprising:
forming at least one trench in a substrate;
forming an isolation layer over the substrate and the at least one trench;
alternately depositing at least one conductive layer and at least one insulator layer over the substrate and the at least one trench;
depositing an upper conductive layer to form the capacitor;
forming a capping layer over the upper conductive layer of the capacitor;
forming one or more dielectric buffer structures on exposed sides of at least one conductive layer of the capacitor;
forming a contact stop layer over an upper surface and sides of the capacitor;
forming electrical contacts to each conductive layer.

20. The method of claim 19, wherein the electrical contacts are formed by etching at least one internal trench to each conductive layer prior to forming the one or more dielectric buffer structures.
